(19) United States
(12) Patent Application Publication
(10) Pub. No.: US 2024/0222288 A1
(43) Pub. Date: Jul. 4, 2024

(54) SOCKET INTERFACE FRAMES FOR DEVICES WITH IMPROVED-PERFORMANCE SUBSTRATES

(71) Applicant: Intel Corporation, Santa Clara, CA (US)

(72) Inventors: David Shia, Portland, OR (US); Timothy Gosselin, Phoenix, AZ (US); Aravindha Antoniswamy, Phoenix, AZ (US); Sergio Antonio Chan Arguedas, Chandler, AZ (US); Elah Bozorg-Grayeli, Chandler, AZ (US); Johnny Cook, JR., Glendale, AZ (US); Steven Klein, Chandler, AZ (US); Rick Canham, Hillsboro, OR (US)

(73) Assignee: Intel Corporation, Santa Clara, CA (US)

(21) Appl. No.: 18/090,140

(22) Filed: Dec. 28, 2022

(51) Int. Cl. H01L 23/544; H01L 23/00; H01L 23/427; H01L 23/49

(52) U.S. Cl. CPC H01L 23/544; H01L 23/427; H01L 23/49; H01L 24/08; H01L 24/48; H01L 2224/08113; H01L 2224/48229; H01L 2924/15165; H01L 2924/1711; H01L 2924/173; H01L 2924/17724; H01L 2924/1776

(57) ABSTRACT

Integrated circuit (IC) device substrates and structures for mating and aligning with sockets. An IC device may include a frame on and around a substrate, which may include glass or silicon. The frame may include an alignment feature, such as a notch or hole, to mate with a complementary keying feature of a socket. A heat spreader may be coupled to an IC die and extend beyond the substrate or be coupled to the frame. The heat spreader may include a heat pipe. The IC device may be part of an IC system with the device substrate coupled to a system substrate by a socket configured to mate to the frame.

### BACKGROUND

End-user demands and other industry constraints continually require integrated circuit (IC) device improvements, such as advances in power and speed capabilities. Such capabilities may be limited, however, by IC device substrates, including their constituent materials, such as organic materials. Plastics, for example, may have lower thermal conductivity, electrical resistivity, stiffness, and moisture resistance than can be found in other materials. Material improvements may require additional or improved structures as new problems are encountered. Structures and materials are needed to improve device substrate performance and reliability.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, and 1C illustrate cross-sectional profile and plan views of an IC device, including an IC die on a device substrate with a frame, in accordance with some embodiments;

FIGS. 2A and 2B illustrate plan views of IC systems, including an IC device with a device substrate coupled by a socket to a system substrate, in accordance with some embodiments;

FIGS. 3A and 3B illustrate cross-sectional profile views of IC systems, including a heat spreader over a device substrate and its frame, in accordance with some embodiments;

FIGS. 4A and 4B illustrate isometric views of an IC device, including an alignment feature between inner and outer perimeters of a frame, in accordance with some embodiments;

FIGS. 5A and 5B illustrate isometric views of an IC device, including an alignment feature between inner and outer perimeters of a frame, in accordance with some embodiments;

FIGS. 6A, 6B, and 6C illustrate isometric views of IC systems, including an IC device having a frame and openings configured to mate with a socket on a system substrate, in accordance with some embodiments;

FIG. 7 is a flow chart of methods for forming an IC system, including coupling an IC device and device substrate to a system substrate by a socket, in accordance with some embodiments;

FIG. 8 illustrates a diagram of an example data server machine employing an IC device having an improved device substrate with a frame, in accordance with some embodiments; and

FIG. 9 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices with IC dies mounted on substrates. Such improvements may be necessary to enable performance, for example, at higher powers and speeds (e.g., clock frequencies). Performance of substrates in IC devices may be increased by using inorganic materials instead of organic substrate materials. For example, relative to organic substrate materials, silicon has a coefficient of thermal expansion likely to more closely match that of an IC die, higher thermal conductivity, higher strength and stiffness, superior surface qualities (e.g., smoothness and flatness), and a lower propensity for absorbing moisture. Glass is also superior in these categories and additionally has a higher resistivity and lower cost than silicon. Other inorganic materials may also improve substrate performance. However, some inorganic materials, such as silicon or glass, may be brittle enough to benefit from structures and methods of handling and manufacture less likely to introduce mechanical defects, e.g., cracks. For example, in some applications, a notch or other opening or cutout may be introduced into a device substrate for keying or aligning the substrate with a socket for coupling the substrate to a host component. Such notching (or similar processing) of a brittle substrate may reduce mechanical strength of the substrate, which may immediately reduce electrical or thermal performance, as well as the durability (e.g., lifetime quality and reliability) of the device.

A frame may be coupled to a device substrate and enable keying or aligning functions without introducing defects into the device substrate. In some embodiments described further below, a frame is coupled to, and extends beyond, the edges of a more mechanically sensitive device substrate. In some such embodiments, the device substrate is coupled to a device host with the frame coupling to a socket on the host. One or more openings in the frame, e.g., notches or holes, may be configured to mate with a receiving socket. Such mating may ensure that the substrate is matched with the intended socket. Such mating may also ensure that the substrate is properly aligned to the socket.

A frame may also enable the mounting of a heat spreader (or of a larger heat spreader than would otherwise be feasible). For example, a heat spreader coupled to the top of an IC die may be vulnerable to mechanical stresses (and breaking) due to handling, e.g., during assembly or when placed in a socket. A frame extending beyond the lateral edges of a device substrate may protect a heat spreader mounted above an IC die and projecting laterally outwards from the die. Such protection may allow for a larger heat spreader over a die, including a heat spreader having a heat pipe or vapor chamber. A heat pipe may hold a working fluid, which may vaporize, to transfer latent heat away from an IC die. Heat pipes of greater length and volume may be capable of dissipating larger quantities of heat away from an IC die. In some embodiments described further below, a heat spreader mounted above an IC die extends beyond the lateral edges of a device substrate. A frame can also serve as a mechanical support for, or an extension of, a heat spreader. In some embodiments, a heat spreader is coupled to a frame on a device substrate.

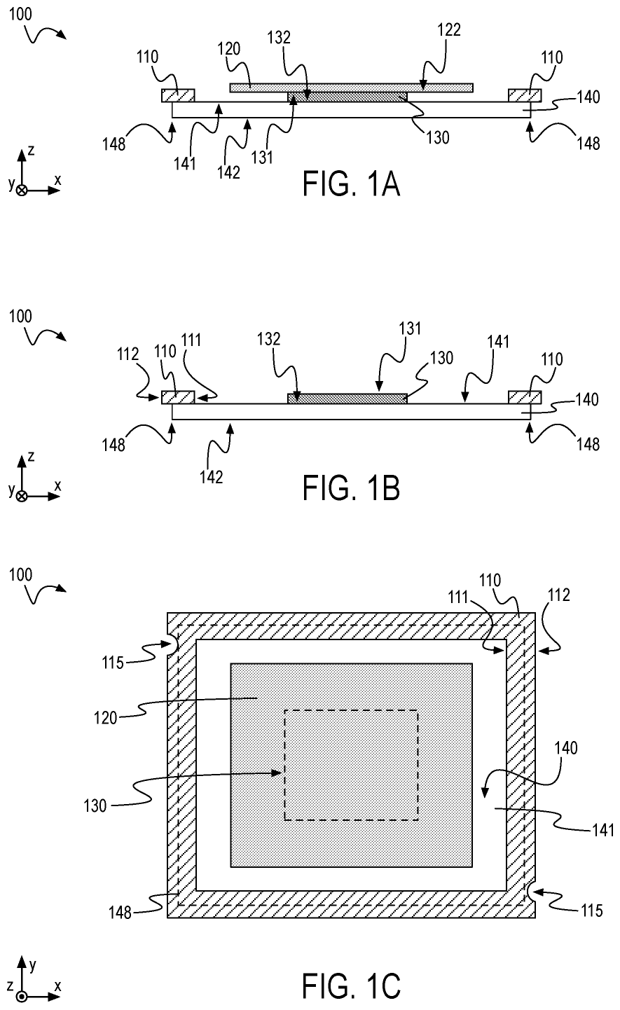

FIGS. 1A, 1B, and 1C illustrate cross-sectional profile and plan views of an IC device 100, including a frame 110 around a device substrate 140 coupled to an IC die 130 with a heat spreader 120, in accordance with some embodiments. FIGS. 1A and 1B show cross-sectional profile views of IC device 100 with a lower surface 132 of IC die 130 coupled (and electrically connected) to upper surface 141 of device substrate 140. Frame 110 is coupled to an outer portion of upper surface 141. The inner portion of upper surface 141 (coupled to IC die 130) is surrounded by an exposed portion of upper surface 141. The outer portion of upper surface 141 (coupled to frame 110) surrounds both the exposed portion and the inner portion. Frame 110 has inner and outer perimeters 111, 112 and extends beyond an outer perimeter 148 of upper surface 141 and device substrate 140. FIG. 1A shows a heat spreader 120 coupled to the upper surface 131 of IC die 130.

Device substrate 140 may include horizontal and vertical electrical lines and other circuit components and connections that support the operation of IC die 130. Device substrate 140 may be an interposer that provides electrical connectivity between contacts (e.g., contact pads, not shown) on die 130 and contacts (not shown) on upper surface 141 and/or lower surface 142 of substrate 140. In one embodiment, substrate 140 includes contact pads (not shown) on surface 142 that are electrically coupled by conductive traces and vias (not shown) in and/or on substrate 140 to contact pads (not shown) on surface 141 that are electrically coupled (e.g., by solder) to contact pads (not shown) on die 130.

Device substrate 140 may include any suitable material. Advantageously, device substrate 140 includes materials with electrical, mechanical, thermal, or other characteristics superior to those of organic materials. In some embodiments, device substrate 140 includes crystalline silicon. In some embodiments, device substrate 140 includes glass, which may be preferable to silicon for lower cost. Inorganic materials may be used in combination with organic materials or other inorganic materials. In some embodiments, device substrate 140 includes a monolithic silicon or glass core between organic layers. For example, device substrate 140 may include a glass layer accounting for 20% of the thickness of device substrate 140 between layers of plastic. Larger thicknesses of silicon or glass may provide more electrical insulation or otherwise improved performance, e.g., at high frequencies. In some embodiments, glass makes up 30% of the thickness of device substrate 140. Multiple layers of silicon or glass may aid in the performance of various substrate functions, e.g., interposing or otherwise routing electrical lines. In some embodiments, one or more glass layers together make up 50% of the thickness of device substrate 140.

The isotropy of a monolithic glass or silicon layer (or a layer at least substantially homogenous or continuous through a cross section of the layer) within device substrate 140 may advantageously provide performance uniformity, e.g., relative to a fiberglass weave in an epoxy resin. A layer of substantially continuous glass may include through-layer vias (or other discrete structures) while maintaining performance benefits, including uniformity, relative to a glass weave or other heterogenous structure. A layer having large sectors or dies with a thickness of substantially homogenous glass or silicon in the layer (e.g., with vias, but not a weave interspersed with resin) may be preferential to fiberglass weave, but may still permit satisfactory mechanical performance, for example, by allowing a certain amount of flexion between sectors. Some such sectors may have lateral areas (e.g., footprints) greater than a lateral area of IC die 130. Some sectors may have lateral areas greater than 90% of a lateral area of device substrate 140, which may provide improved electrical performance relative to smaller footprints.

A high-performance IC die 130 (e.g., a high-speed memory device or high-speed and -power processor) may benefit most from high-performance device substrate 140, but IC die 130 may be of any suitable type. IC die 130 may include any suitable material or materials. For example, IC die 130 may include a semiconductor material such as monocrystalline silicon, germanium, silicon germanium, silicon carbide, sapphire (Al₂O₃), a III-V alloy material (e.g., gallium arsenide), or any combination thereof. IC die 130 may include various metallization (e.g., copper, aluminum, etc.) and dielectric (e.g., silicon oxides and other) structures. IC die 130 may have front- and back-sides. The lower surface 132 of IC die 130 may include metallization structures, such as bond pads or other interconnect interfaces, coupled to upper surface 141 of device substrate 140. Lower surface 132 of IC die 130 may be coupled to upper surface 141 of device substrate 140 by any suitable means, e.g., soldering.

Frame 110 is affixed to device substrate 140 at an outer portion of upper surface 141. Frame 110 extends beyond outer perimeter 148 of upper surface 141 and device substrate 140, which may allow frame 110 to couple to a socket, as will be described below. Frame 110 may be attached to device substrate 140 by any suitable means, e.g., by an adhesive. In the example of FIG. 1A, frame 110 is affixed to the outer portion of upper surface 141 by an epoxy. In some embodiments, frame 110 is soldered to device substrate 140. Frame 110 and device substrate 140 may be coupled by other means.

Frame 110 may be used to mechanically handle and to mount device substrate 140. Frame 110 is advantageously primarily of a material other than the inorganic material utilized in device substrate 140. Frame 110 may be of any suitable material(s) of sufficient mechanical strength and/or toughness. For example, frame 110 may be of a material with a greater fracture toughness (e.g., K_{Ic}, as measured in MPa*m^{1/2}) than a material of device substrate 140. Frame 110 may be a single piece of, e.g., metal, such as aluminum. In some embodiments, frame 110 includes steel, such as stainless steel. Steels may have greater toughness relative to other materials, e.g., aluminum alloys, while aluminum (or an aluminum alloy) may have the benefits of sufficient toughness and lower cost.

Heat spreader 120 spreads heat or thermal energy, e.g., away from IC die 130. Such heat dissipation may improve the performance and reliability of IC die 130 by limiting maximum die temperature. Advantageously, heat spreader 120 is predominantly of a thermally conductive material and has a greater surface area than upper IC die surface 131 to which it is coupled. For example, heat spreader 120 may be a metal. In the example of FIG. 1A, heat spreader 120 is a copper structure, a material more thermally conductive than the bulk of IC die 130, e.g., silicon.

Heat spreader 120 may include other materials (e.g., surface finishes, etc.). Advantageously, heat spreader 120 is thin enough to effectively conduct thermal energy from its die (lower) side up, out, and away from IC die 130. In some embodiments, heat spreader 120 has a thickness of 20 um. Advantageously though, heat spreader 120 is thick enough to effectively conduct thermal energy from its center (at the die) laterally outwards and away from IC die 130. In some embodiments, heat spreader 120 has a thickness of 30 um. In some embodiments, heat spreader 120 has a non-uniform thickness, e.g., to optimize both heat conductance away from IC die 130 (e.g., thicker near die) and heat transfer area at its edges (e.g., thin fins, which may include vertically oriented portions).

Heat spreader 120 is coupled to IC die 130 with lower surface 122 of heat spreader 120 coupled to upper surface 131 of IC die 130 opposite device substrate 140. Heat spreader 120 may be coupled to IC die 130 by any suitable means, e.g., affixed or bonded by a thermally conductive material. In some embodiments, heat spreader 120 is bonded to upper surface 131 by solder or other thermal interface material.

In some embodiments, heat spreader 120 is absent, e.g., for low-power applications. FIG. 1B shows a cross-sectional profile view of IC device 100 with IC die 130 mounted on device substrate 140 and no heat spreader 120 on IC die 130.

FIG. 1C shows a plan view of IC device 100, including frame 110 and heat spreader 120 over device substrate 140. An outline of IC die 130 (which is coupled to and under heat spreader 120) is illustrated as a dashed line. Frame 110 is a single, continuous piece of material (e.g., metal) attached to an outer portion of upper surface 141. IC die 130 is coupled to an inner portion of upper surface 141. An intervening portion of upper surface 141 is between frame 110 and IC die 130. Frame 110 extends beyond, and encircles, outer perimeter 148 (illustrated as a dashed line) of device substrate 140. Frame 110 has inner and outer perimeters 111, 112. Inner perimeter 111 is around the intervening portion of upper surface 141 and IC die 130. Outer perimeter 112 is around inner perimeter 111.

Frame 110 may be configured to key to a socket. With its superior mechanical properties, the frame can protect substrate 140 from any operations that the key. Openings 115 in outer perimeter 112 of frame 110 are beyond outer perimeter 148 (of device substrate 140) and allow for mating frame 110 (and so IC device 100) with a socket, e.g., on either side of frame 110 and device substrate 140. Each opening 115 is (or is part of) an alignment feature configured to mate with a complementary structure of a socket to receive IC device 100. Openings 115 are of a shape to receive the socket's matching keying features (as will be described below). In some embodiments, frame 110 includes a single alignment feature, e.g., opening 115. In some embodiments, frame 110 includes multiple, e.g., four, sides with a corresponding opening 115 alignment feature on each side. In some embodiments, frame 110 includes more alignment feature openings 115 than sides. Although embodiments may be shown or described as having openings or voids in frame 110 as (negative) alignment features, frame 110 may include positive alignment features, such as tabs, posts, or other protrusions that may mate with a negative feature in a socket.

In the example of FIGS. 1A and 1C, heat spreader 120 extends laterally beyond the perimeter of IC die 130. Other sizes of heat spreader 120 may be coupled to IC die 130. Frame 110 extends the footprint of IC device 100 and so facilitates more and larger possible instances of heat spreader 120. For at least some range of areas of heat spreader 120 greater than the area of IC die 130, larger dimensions (and corresponding areas) of heat spreader 120 may result in a greater quantity of heat transferred out of IC die 130.

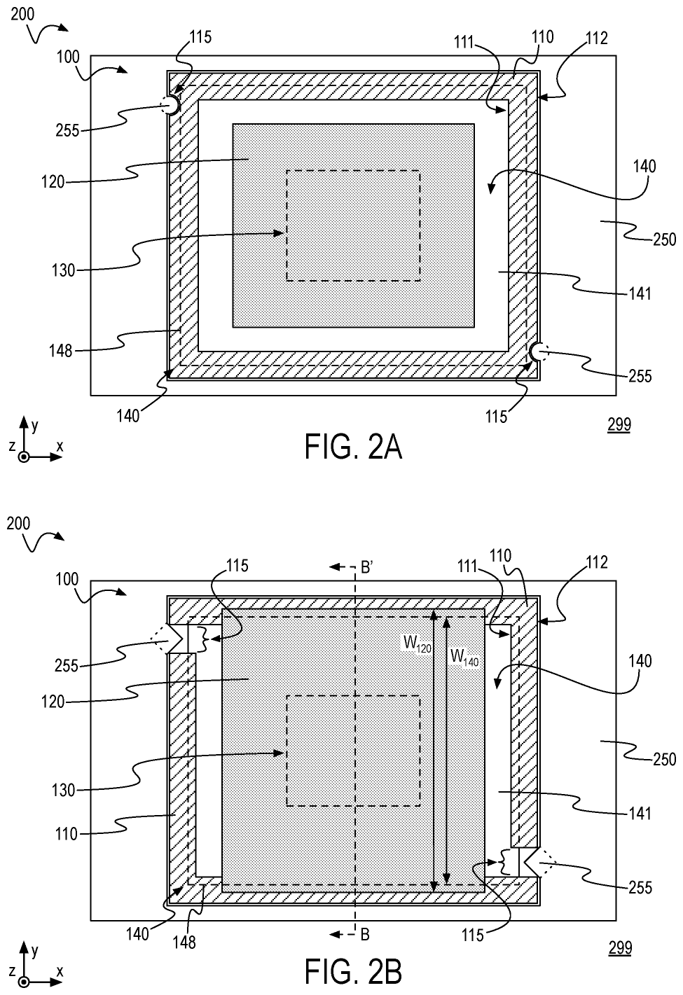

FIGS. 2A and 2B illustrate plan views of IC systems 200, including IC device 100 with device substrate 140 coupled by socket 250 to system substrate 299, in accordance with some embodiments. FIG. 2A shows IC system 200 with socket 250 over, and coupled to, system substrate 299. A same or similar IC device 100 shown and described in FIG. 1C is in socket 250 with device substrate 140 over and coupled to system substrate 299 by socket 250. IC die 130 is over and coupled to the center portion of upper surface 141 of outer perimeter 148. Frame 110 is attached to the outermost portion of upper surface 141 and extends past outer perimeter 148 of device substrate 140 on all sides. An intervening portion of upper surface 141 surrounds IC die 130 and is between IC die 130 and frame 110.

Frame 110 has openings 115 in outer perimeter 112 of frame 110 (or between socket 250 and outer perimeter 112) and adjacent socket 250. Voids or openings 115 are alignment features configured to mate with keying features 255 and pair with socket 250. Keying features 255 are structures complementary to voids or openings 115, such that socket 250 is configured to mate with frame 110. For example, in FIG. 2A (and FIG. 1C), openings 115 are concavities configured to mate with the matching convex protrusions of keying features 255 extending inward from inner surfaces of socket 250 on both sides of frame 110. By matching to openings 115, keying features 255 may perform an aligning function, ensuring that frame 110 (and so IC device 100) is properly positioned (e.g., aligned) relative to socket 250 and over system substrate 299. Keying features 255 (and so socket 250) may also be designed to match with voids or openings 115 in certain frames 110 and to not match with voids or openings 115 in other frames 110. Keying features 255 or openings 115 may be situated in different positions, increased or decreased in size, etc., to match (or not match) with each other. Keying feature 255 may be on or integrated with an inner surface of socket 250 (e.g., running vertically up the full height of an inner surface of socket 250) or may extend vertically up from a lateral surface in the inner opening of socket 250. In some embodiments, and as described previously, frame 110 may have a positive alignment feature (e.g., a tab or post) that extends or protrudes from frame 110 to mate with a complementary negative keying feature of socket 250 (e.g., a slot or notch or hole).

System substrate 299 may be any host component with socket 250 coupled to it, such as a printed circuit board (PCB). System substrate 299 may be coupled to another host component, e.g., between and coupling socket 250 and system substrate 299 or between system substrate 299 and a power supply.

In the example of FIG. 2A, heat spreader 120 is predominantly copper but with an additional layer of nickel, for example, plated onto the copper.

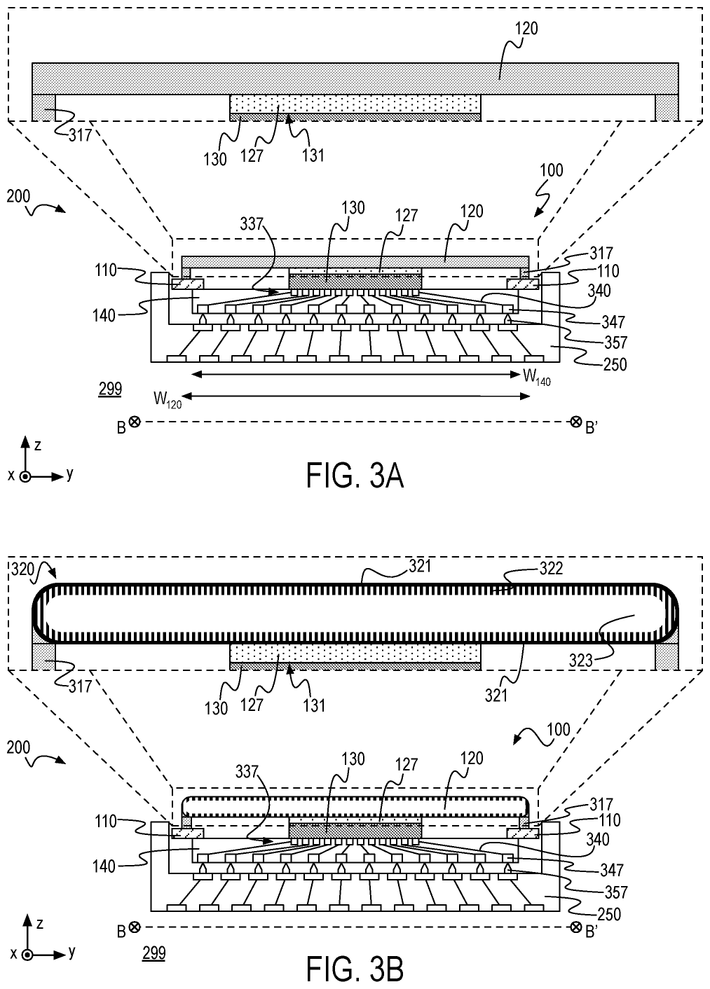

FIG. 2B shows a plan view of IC system 200 having socket 250 over, and coupled to, system substrate 299. The plan view of FIG. 2B includes reference line B-B′, which is in the viewing planes, and indicates the orientation, of the cross-sectional profile views of FIGS. 3A and 3B. In the y direction of the example of FIG. 2B, a lateral dimension W₁₂₀ of heat spreader 120 is greater than a lateral dimension W₁₄₀ of device substrate 140. Heat spreader 120 extends laterally in the y direction beyond outer perimeter 148 on those sides of device substrate 140. The larger area of heat spreader 120 is enabled by frame 110 and its expansion of the footprint of IC device 100.

In the example of FIG. 2B, frame 110 includes more than one constituent piece. Openings 115 in frame 110 extend from inner perimeter 111 to outer perimeter 112, separating frame 110 into two pieces, one above and one below openings 115. The two pieces or elements of frame 110 are affixed by epoxy to the outer portion of device substrate 140. Frame 110 extends beyond outer perimeter 148. Openings 115 are alignment features in frame 110 extending beyond outer perimeter 148. Alignment features and openings 115 mate with complementary keying features 255 of socket 250 to receive IC device 100. In some embodiments, frame 110 includes multiple abutting pieces. For example, a piece with an opening 115 or other alignment feature may be attached to another piece attached to and around an outer portion of device substrate 140. In some such embodiments, the alignment feature may extend outward to mate with an opening in an inner surface of socket 250.

FIGS. 3A and 3B illustrate cross-sectional profile views of IC systems 200, including heat spreaders 120 over frames 110 and extending laterally beyond device substrates 140, in accordance with some embodiments. A section of FIGS. 3A and 3B including heat spreader 120 is expanded and shows details of and around heat spreader 120. The cross-sectional profile views of FIGS. 3A and 3B include schematic representations of the electrical routing in, e.g., device substrate 140 and socket 250. The electrical routing of device substrate 140 or socket 250 may interpose a fine pitch of IC die 130 out to a wider pitch on system substrate 299. The electrical routing may serve as an interface between IC die 130 to a standard pinout on system substrate 299. Electrical lines 340 in device substrate 140 couple and electrically connect IC die 130 and socket interconnect interfaces 357. Upper substrate interconnect interfaces 337 contact pads (not shown) on IC die 130. Lower substrate interconnect interfaces 347 contact socket interconnect interfaces 357. Socket interconnect interfaces 357 couple and electrically connect lower substrate interconnect interfaces 347 on device substrate 140 to socket 250. As shown, socket interconnect interfaces 357 are pins. Other interfaces are possible.

FIG. 3A shows a cross-sectional profile view of IC system 200 having IC device 100 with device substrate 140 coupled to system substrate 299 by socket 250. Notably, heat spreader 120 extends laterally beyond the outer perimeter of device substrate 140. Lateral dimension W₁₂₀ of heat spreader 120 is greater than lateral dimension W₁₄₀ of device substrate 140. Heat spreader 120 extends out, and is coupled, to frame 110. Heat spreader 120 is coupled to frame 110 and mechanically supported by support structures 317. In the example of FIG. 3A, support structures 317 are laterally beyond the outer perimeter of device substrate 140. Frame 110 and its expansion of the footprint of IC device 100 facilitates the coupling to and supporting of heat spreader 120 by support structures 317. In some embodiments, support structures 317 are of (or include) a thermally conductive material, such as a metal, and heat spreader 120 is thermally coupled to frame 110 by support structures 317. In some embodiments, frame 110 can be thought of as part of a two-piece heat spreader. In some such embodiments, frame 110 includes a thermally conductive material, for example, copper. In some embodiments, frame 110 is coupled (or directly connected) to heat spreader 120 without support structure 317.

Heat spreader 120 is coupled, e.g., thermally, to upper surface 131 of IC die 130 by a thermal interface material (TIM) 327. TIM 327 is a material between heat spreader 120 and upper surface 131 that enhances the thermal coupling between heat spreader 120 and upper surface 131. In the example of FIG. 3A, TIM 327 is a thermal adhesive. In some embodiments, a metal TIM (such as solder) thermally couples support structure 317 to heat spreader 120 or support structures 317 to frame 110. In some embodiments, one of these or another TIM (such as a thermal paste, thermal gap filler, thermally conductive pad, thermal tape, etc.) thermally couples heat spreader 120 to upper surface 131 or support structure 317. In some embodiments, a TIM thermally couples heat spreader 120 or support structure 317 to frame 110.

Electrical lines 340 in device substrate 140 schematically represent electrical connections between IC die 130 and socket interconnect interfaces 357. In some embodiments, device substrate 140 includes conductive traces (e.g., as portions of lines 340) in or on one or more insulating layers, e.g., a redistribution layer (RDL), for example, above and below a monolithic layer of glass. In some embodiments, device substrate 140 includes through-glass vias, e.g., portions of lines 340 running substantially vertically through the thickness of the glass and coupling an upper RDL to a lower RDL. For example, an upper RDL may redistribute or couple die contacts out to the vias, and a lower RDL may couple the vias to the contact pads for the socket.

FIG. 3B shows a cross-sectional profile view of a similar IC system 200 with IC device 100 and device substrate 140 coupled to system substrate 299 by socket 250. Notably, heat spreader 120 includes a heat pipe 320 (which is shown in the expanded view) and extends laterally beyond the outer perimeter of device substrate 140. A lateral width of heat spreader 120 is greater than a lateral width of device substrate 140. Heat spreader 120 is coupled to frame 110 and mechanically supported by support structures 317. TIM 327 is between heat spreader 120 and upper surface 131 of IC die 130.

Heat spreader 120 and heat pipe 320 include an envelope 321, a capillary section or wick 322, and working fluid 323. Heat pipe 320 may enhance heat transfer away from IC die 130. Working fluid 323 may absorb the heat from IC die 130 at a hot interface and vaporize due to the pressure and elevated temperature in envelope 321. Working fluid 323 may condense at a cold interface and transfer its latent heat away from IC die 130. The condensed working fluid 323 may return to the hot interface from the cold interface by the capillary section or wick 322. Heat pipe 320 with larger dimensions may transfer more heat away from IC die 130.

Working fluid 323 and the material for envelope 321 may preferentially be chosen for compatibility with each other, e.g., without developing large amounts of non-condensable gas or oxidation products. Material-fluid pairs may be chosen based on temperature operating range. For example, water, methanol, or R134a may be chosen as working fluids 323 compatible with copper envelopes 321. Methanol may be selected for a lower temperature range than water, and R134a may be chosen for a still lower temperature range. Other envelopes 321 or working fluids 323 may be chosen.

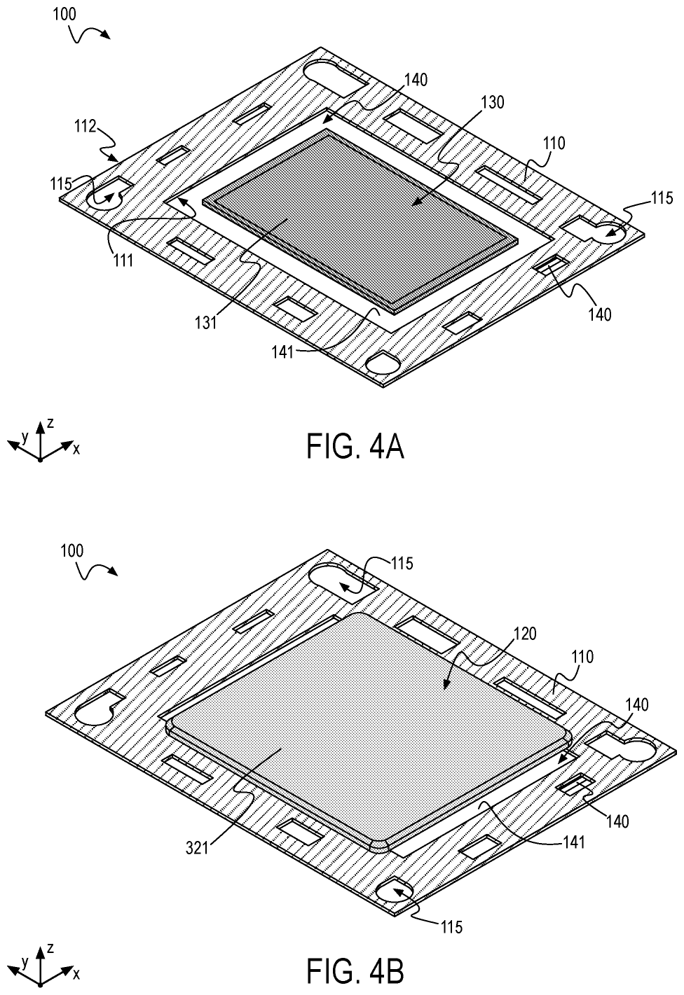

FIGS. 4A and 4B illustrate isometric views of IC device 100, including alignment feature openings 115 in frame 110 between inner and outer perimeters 111, 112, in accordance with some embodiments. FIG. 4A shows openings 115 between inner and outer perimeters 111, 112 of a continuous metal frame 110. While at least some of the previously described embodiments had voids or openings 115 in outer perimeter 112 and adjacent a socket, some openings 115 may be configured to receive socket keying features interior to outer perimeter 112 of frame 110. Frame 110 is coupled to upper surface 141 and encircles an outer edge or perimeter of device substrate 140. Frame 110 has an alignment feature that includes at least one of openings 115 configured to receive a keying feature of a socket. Each opening 115 configured to receive a keying feature of a socket may be considered an alignment feature, and an alignment feature may include one or more of openings 115. Inner perimeter 111 is around IC die 130, and outer perimeter 112 is around inner perimeter 111. Openings 115 are each a void bounded by frame 110 between inner and outer perimeters 111, 112. As will be described below, such openings may be configured to mate with complementary keying features in a socket, e.g., keying features not immediately adjacent a vertical, inner surface of a socket. Some openings may be configured to mate with complementary keying features in another socket. Some openings may serve other functions.

FIG. 4B shows the same or a similar IC device 100 with openings 115 enclosed between inner and outer perimeters 111, 112 of a continuous metal frame 110. IC device 100 includes a large heat spreader 120, including a heat pipe with envelope 321 of predominantly copper containing water as working fluid 323. Heat spreader 120 is coupled to upper surface 131 of IC die 130 and to frame 110. In some embodiments, heat spreader 120 is coupled to frame 110 with a TIM. Heat spreader 120 extends laterally beyond the outer edge of upper surface 141 of device substrate 140. A lateral width of heat spreader 120 is greater than a lateral width of device substrate 140.

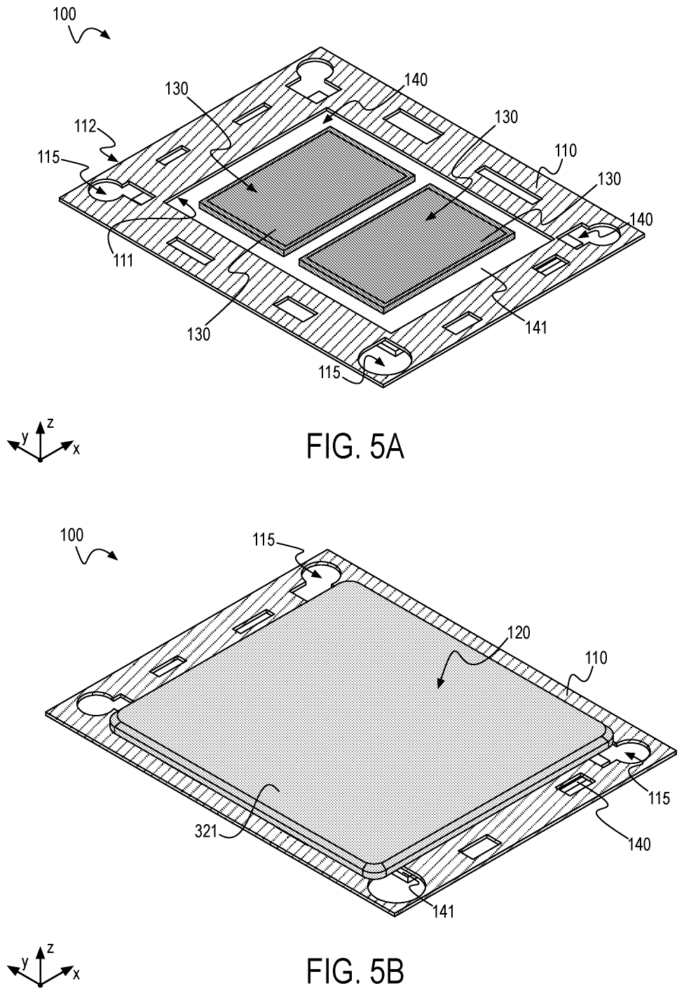

FIGS. 5A and 5B illustrate isometric views of IC device 100, including alignment feature openings 115 in frame 110 between inner and outer perimeters 111, 112, in accordance with some embodiments. FIG. 5A shows IC device 100 similar to that of FIG. 4A, with a continuous metal frame 110 having openings 115 between inner and outer perimeters 111, 112, but with different IC dies 130. Openings 115 are different from those of FIG. 4A, e.g., to ensure that IC device 100 is not placed in a socket configured for IC device 100 (and frame 110 and openings 115) of FIG. 4A. Frame 110 and openings 115 of FIGS. 5A and 5B are configured to pair with a different socket than that meant for frame 110 and openings 115 of FIG. 4A. Openings 115 are differently shaped or sized alignment features to mate with complementary structures of a different socket than the socket meant to receive IC device 100 of FIG. 4A.

FIG. 5B shows the same or a similar IC device 100 as that of FIG. 5A, but with IC dies 130 coupled to a large heat spreader 120, including a heat pipe with envelope 321 of predominantly copper containing methanol as working fluid 323. Single heat spreader 120 is coupled to upper surfaces 131 of both IC dies 130 (which are hidden under heat spreader 120). In some embodiments, IC device 100 includes a separate heat spreader 120 for each IC die 130. Heat spreader 120 extends laterally beyond the outer edge of upper surface 141 of device substrate 140. A lateral width of heat spreader 120 is greater than a lateral width of device substrate 140. In some embodiments, heat spreader 120 is coupled to frame 110 with support structures coupling with openings 115.

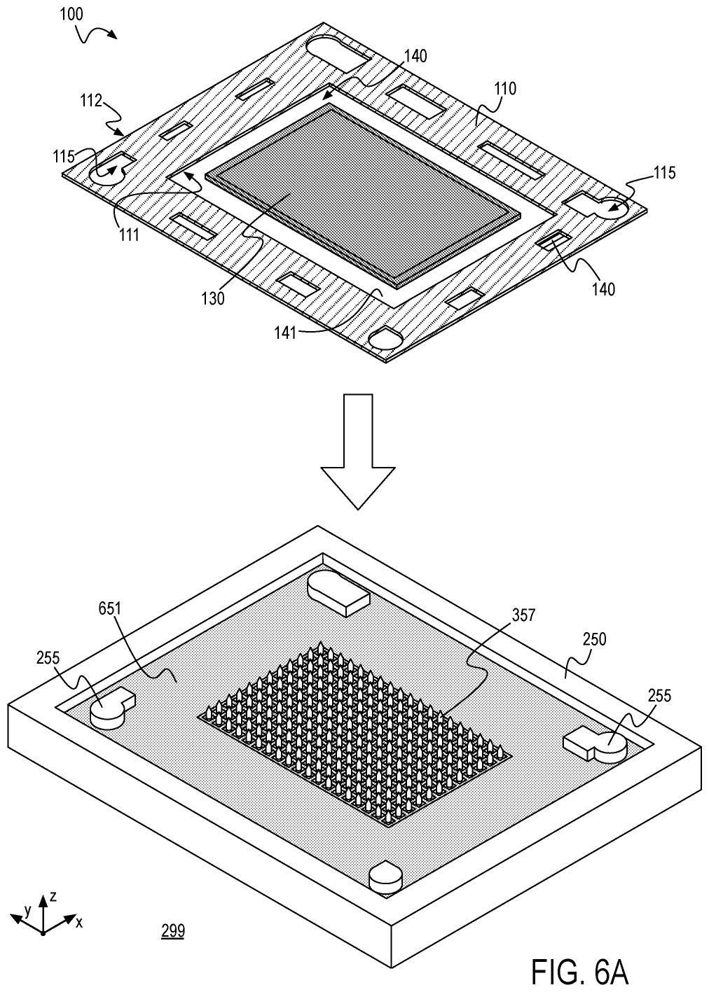

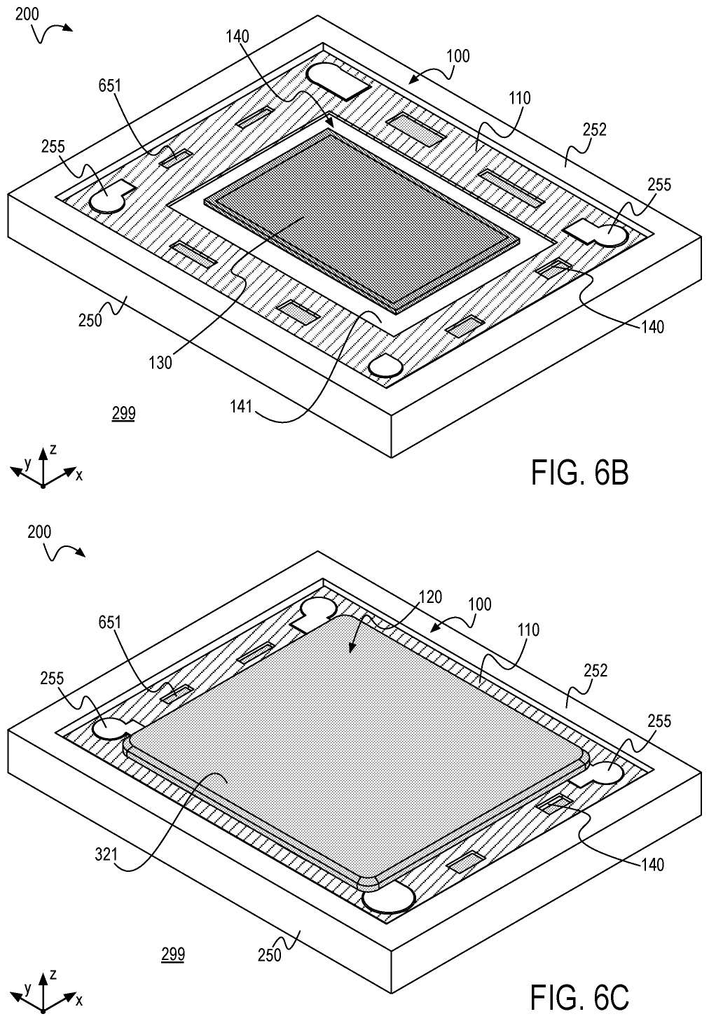

FIGS. 6A, 6B, and 6C illustrate isometric views of IC systems 200, including IC device 100 with frame 110 having openings 115 configured to mate with socket 250 on system substrate 299, in accordance with some embodiments. FIG. 6A shows socket 250 configured and aligned to mate to frame 110 of IC device 100. IC device 100 is the same or similar to IC device 100 of FIG. 4A. Openings 115 in frame 110 are configured and aligned to pair with socket 250. Socket 250 includes keying features 255 configured to mate with openings 115 in frame 110. Openings 115 are between inner perimeter 111 and outer perimeter 112, encircled or surrounded by frame 110. Keying features 255 and socket interconnect interfaces 357 extend up from an inner lateral surface 651 of socket 250. Socket interconnect interfaces 357 may be pins or other metallization structures meant to contact interconnect interfaces on an underside of device substrate 140. Socket interconnect interfaces 357 may extend upwards with a spring force and so maintain contact with corresponding interconnect interfaces

FIG. 6B shows IC system 200 with the example IC device 100 and socket 250 of FIG. 6A. IC device 100 and device substrate 140 are coupled to system substrate 299 by socket 250. IC device 100 and device substrate 140 are aligned by frame 110 and its openings 115. Socket 250 includes keying features 255 mated with selected openings 115 in frame 110. Each of openings 115 that are mated with a corresponding keying feature 255 are an alignment feature of frame 110. Inner lateral surface 651 can be seen through other openings 115 as frame 110 extends beyond the outer edges of device substrate 140.

Socket 250 may include, e.g., on an upper surface 252 of socket 250, a structure to secure IC device 100 in socket 250, for example, with a downward force to oppose upward spring forces from below. Such a structure may include a lever or latch and fasten, e.g., frame 110 down. In some embodiments, a structure presses down on IC die 130. In some embodiments, a structure is coupled to system substrate 299 but not upper surface 252.

FIG. 6C shows a similar IC system 200 with IC device 100 in socket 250. However, IC device 100 is the same or similar to IC device 100 of FIG. 5B and includes heat spreader 120. Heat spreader 120 (with heat pipe envelope 321) is coupled to the upper surfaces of IC dies obscured by heat spreader 120. The IC dies are coupled to an upper surface 141 of device substrate 140. IC device 100 and device substrate 140 are coupled to system substrate 299 by socket 250. Socket 250 and keying features 255 are mated with selected openings 115 in frame 110. Frame 110 extends beyond the outer edges of device substrate 140. Heat spreader 120 extends, e.g., in the x direction, beyond at least some of the outer edges of device substrate 140.

Notably, keying features 255 are complementary structures configured to mate with selected openings 115 and frame 110 in FIG. 6C. Each of openings 115 mated with a corresponding keying feature 255 are an alignment feature of frame 110 in FIG. 6C and would not mate with, e.g., socket 250 of FIG. 6B or any of its keying features 255. Frame 110 in FIG. 6B and its openings 115 are not configured to mate with openings 115 and frame 110 in FIG. 6C.

A structure to secure IC device 100 in socket 250 may be the same or similar to an equivalent structure in FIG. 6B. In other embodiments, an equivalent structure, such as a latch, better accommodates heat spreader 120 and engages only with outer portions of frame 110.

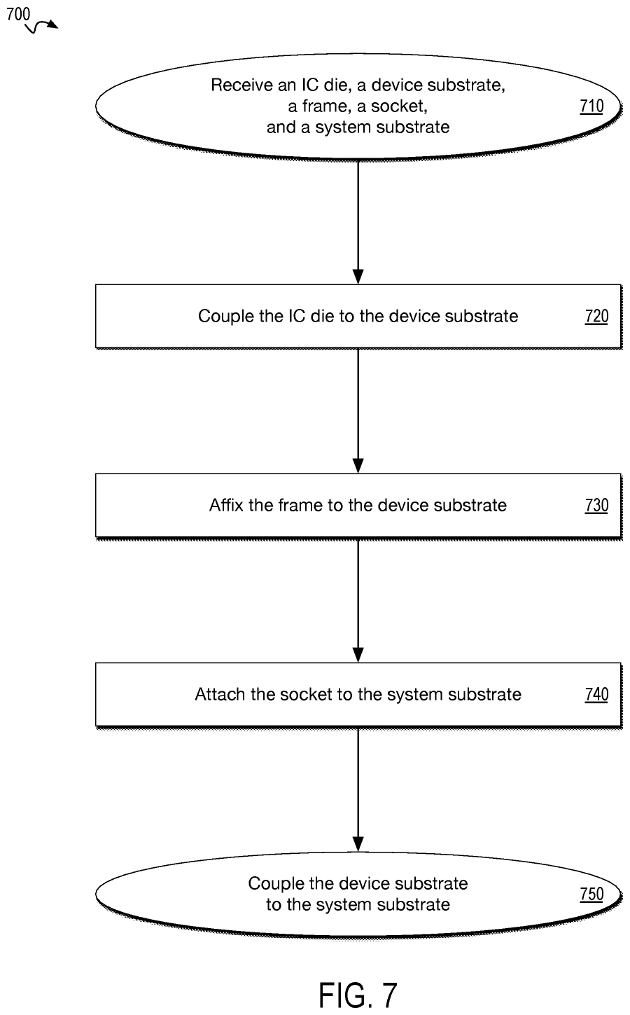

FIG. 7 is a flow chart of methods 700 for forming an IC system, including coupling an IC device and a device substrate with a frame to a system substrate with a socket, in accordance with some embodiments. Methods 700 include operations 710-750. Some operations shown in FIG. 7 are optional. Additional operations may be included. FIG. 7 shows an example sequence, but the operations can be done in other orders as well, and some operations may be omitted. Some operations can also be performed multiple times before other operations are performed. For example, multiple IC dies may be coupled to the device substrate. Some operations may be included within other operations so that the number of operations illustrated FIG. 7 is not a limitation of the methods 700.

Methods 700 begin with receiving an IC die, a device substrate, a frame, a socket, and a system substrate at operation 710. In some embodiments, a heat spreader is also received. In some embodiments, parts or materials for the received structures and the structures may be formed from the parts or materials. For example, metal may be received for forming a frame.

In operation 720, the IC die is coupled to the device substrate. In some embodiments, the IC die is received coupled to the device substrate. The IC die and device substrate may be coupled by any suitable means. In some embodiments, the IC die is soldered to the substrate. In some embodiments, interconnect interfaces, such as metallization structures, on the IC die and device substrate are direct bonded.

In operation 730, the frame is affixed to the device substrate. The frame may be attached to an upper surface of the device substrate using an adhesive. In some such embodiments, the frame is affixed to an outer portion of the device substrate by an epoxy. The frame may be attached by any suitable means.

In some embodiments, the frame is formed, for example, from received metal. In some embodiments, a flat piece of metal is cut to the proper shape. Such a shape may be configured to mate to an intended socket. For example, the shape may include inner and outer perimeters (e.g., with an inner perimeter around a central opening meant for one or more IC dies, and an outer perimeter around the inner perimeter) and at least one opening or void to receive a keying feature of a socket. The void may be between the inner and outer perimeters (e.g., a hole through, and encircled by, the frame) or in the outer perimeter (e.g., adjacent the socket, such as a notch in the outer edge of the frame). In other embodiments, a frame may be shaped to include an alignment feature that is configured to extend outward, e.g., laterally, to mate with a complementary feature in a socket, e.g., a slot.

In operation 740, the socket is attached to the system substrate. Attaching the socket and system substrate may include making electrical connections between corresponding interconnect interfaces, such as metallization structures. In some embodiments, the socket is soldered to the system substrate. In some embodiments, a spring force presses corresponding interconnect interfaces to maintain contact. In some embodiments, the socket is attached to the system substrate with an epoxy. In some embodiments, socket and system substrate are received already coupled.

In operation 750, the system substrate is coupled to the device substrate. The device substrate may be coupled to the system substrate by aligning the device substrate and frame of the IC device in the socket (e.g., attached to the system substrate) and inserting the IC device. Aligning the frame with the socket may include aligning an opening (e.g., a notch or hole) in the frame with a complementary keying feature of the socket (e.g., a tab or post) that fits into the notch or hole. Coupling the system substrate to the device substrate may include contacting corresponding interconnect interfaces, such as metallization structures, on the substrates. For example, coupling the substrates may include contacting one or more pin(s) in a socket on the system substrate to one or more matching metal pad(s) on the device substrate. A socket on a system substrate may include a latch, and a device substrate, coupled to a system substrate by aligning and inserting in a socket, may be secured by latching the device substrate in the socket. Other securing means may be suitable. For example, an IC device (and frame) may click or be clipped into detents that mechanically secure the frame (and so the IC device).

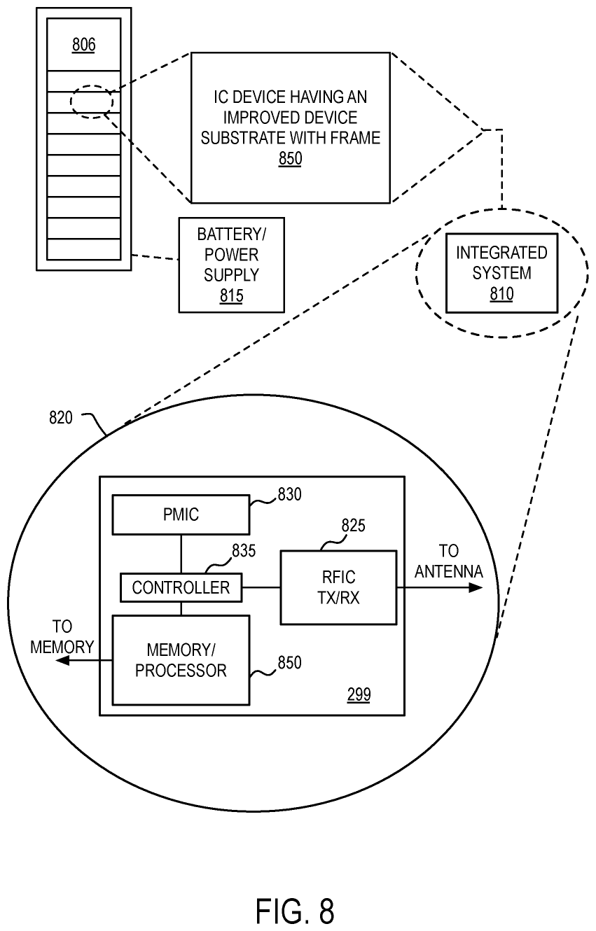

FIG. 8 illustrates a diagram of an example data server machine 806 employing an IC device having an improved device substrate with a frame, in accordance with some embodiments. Server machine 806 may be any commercial server, for example, including any number of high-performance computing platforms disposed within a rack and networked together for electronic data processing, which in the exemplary embodiment includes one or more devices 850 having an improved device substrate with a frame.

Also as shown, server machine 806 includes a battery and/or power supply 815 to provide power to devices 850, and to provide, in some embodiments, power delivery functions such as power regulation. Devices 850 may be deployed as part of a package-level integrated system 810. Integrated system 810 is further illustrated in the expanded view 820. In the exemplary embodiment, devices 850 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 850 is a microprocessor including a static RAM (SRAM) cache memory. As shown, device 850 may be an IC device having an improved device substrate with a frame, as discussed herein. Device 850 may be further coupled to (e.g., communicatively coupled to) a board, an interposer, or a system substrate 299 along with, one or more of a power management IC (PMIC) 830, RF (wireless) IC (RFIC) 825 including a wideband RF (wireless) transmitter and/or receiver (TX/RX) (e.g., including a digital baseband and an analog front end module further includes a power amplifier on a transmit path and a low noise amplifier on a receive path), and a controller 835 thereof. In some embodiments, RFIC 825, PMIC 830, controller 835, and device 850 include an improved device substrate with a frame.

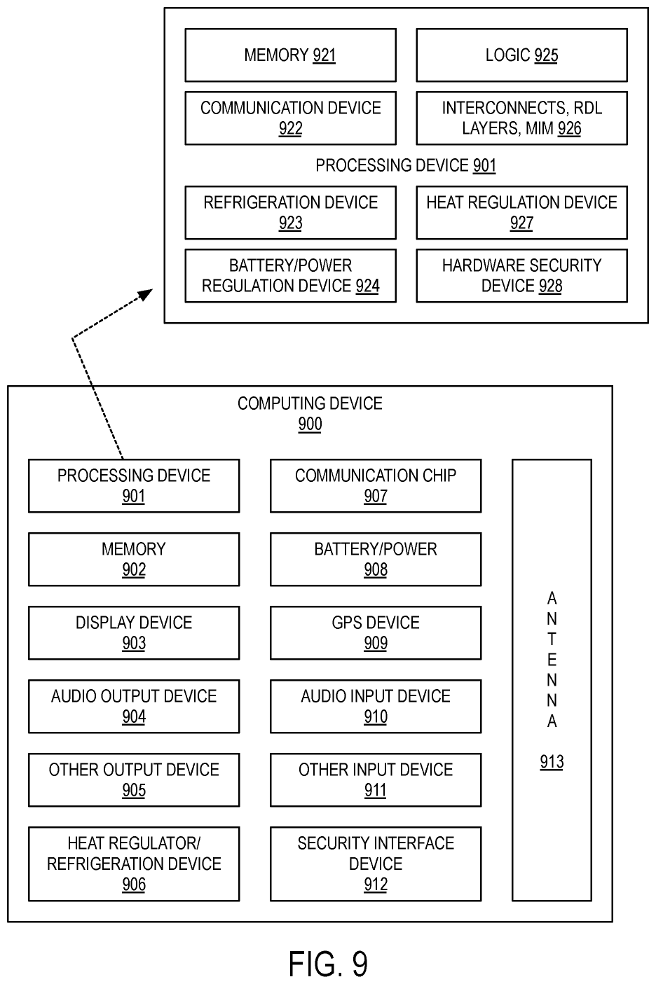

FIG. 9 is a block diagram of an example computing device 900, in accordance with some embodiments. For example, one or more components of computing device 900 may include any of the devices or structures discussed herein. A number of components are illustrated in FIG. 9 as being included in computing device 900, but any one or more of these components may be omitted or duplicated, as suitable for the application. In some embodiments, some or all of the components included in computing device 900 may be attached to one or more printed circuit boards (e.g., a motherboard). In some embodiments, various ones of these components may be fabricated onto a single system-on-a-chip (SoC) die. Additionally, in various embodiments, computing device 900 may not include one or more of the components illustrated in FIG. 9, but computing device 900 may include interface circuitry for coupling to the one or more components. For example, computing device 900 may not include a display device 903, but may include display device interface circuitry (e.g., a connector and driver circuitry) to which display device 903 may be coupled. In another set of examples, computing device 900 may not include an audio output device 904, other output device 905, global positioning system (GPS) device 909, audio input device 910, or other input device 911, but may include audio output device interface circuitry, other output device interface circuitry, GPS device interface circuitry, audio input device interface circuitry, audio input device interface circuitry, to which audio output device 904, other output device 905, GPS device 909, audio input device 910, or other input device 911 may be coupled.

Computing device 900 may include a processing device 901 (e.g., one or more processing devices). As used herein, the term “processing device” or “processor” indicates a device that processes electronic data from registers and/or memory to transform that electronic data into other electronic data that may be stored in registers and/or memory. Processing device 901 may include a memory 921, a communication device 922, a refrigeration device 923, a battery/power regulation device 924, logic 925, interconnects 926 (i.e., optionally including redistribution layers (RDL) or metal-insulator-metal (MIM) devices), a heat regulation device 927, and a hardware security device 928.

Processing device 901 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 900 may include a memory 902, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 902 includes memory that shares a die with processing device 901. This memory may be used as cache memory and may include embedded dynamic random-access memory (eDRAM) or spin transfer torque magnetic random-access memory (STT-MRAM).

Computing device 900 may include a heat regulation/refrigeration device 906. Heat regulation/refrigeration device 906 may maintain processing device 901 (and/or other components of computing device 900) at a predetermined low temperature during operation.

In some embodiments, computing device 900 may include a communication chip 907 (e.g., one or more communication chips). For example, the communication chip 907 may be configured for managing wireless communications for the transfer of data to and from computing device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 907 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 907 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network.

Communication chip 907 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 907 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 907 may operate in accordance with other wireless protocols in other embodiments. Computing device 900 may include an antenna 913 to facilitate wireless communications and/or to receive other wireless communications (such as AM or FM radio transmissions).

In some embodiments, communication chip 907 may manage wired communications, such as electrical, optical, or any other suitable communication protocols (e.g., the Ethernet). As noted above, communication chip 907 may include multiple communication chips. For instance, a first communication chip 907 may be dedicated to shorter-range wireless communications such as Wi-Fi or Bluetooth, and a second communication chip 907 may be dedicated to longer-range wireless communications such as GPS, EDGE, GPRS, CDMA, WiMAX, LTE, EV-DO, or others. In some embodiments, a first communication chip 907 may be dedicated to wireless communications, and a second communication chip 907 may be dedicated to wired communications.

Computing device 900 may include battery/power circuitry 908. Battery/power circuitry 908 may include one or more energy storage devices (e.g., batteries or capacitors) and/or circuitry for coupling components of computing device 900 to an energy source separate from computing device 900 (e.g., AC line power).

Computing device 900 may include a display device 903 (or corresponding interface circuitry, as discussed above). Display device 903 may include any visual indicators, such as a heads-up display, a computer monitor, a projector, a touchscreen display, a liquid crystal display (LCD), a light-emitting diode display, or a flat panel display, for example.

Computing device 900 may include an audio output device 904 (or corresponding interface circuitry, as discussed above). Audio output device 904 may include any device that generates an audible indicator, such as speakers, headsets, or earbuds, for example.

Computing device 900 may include an audio input device 910 (or corresponding interface circuitry, as discussed above). Audio input device 910 may include any device that generates a signal representative of a sound, such as microphones, microphone arrays, or digital instruments (e.g., instruments having a musical instrument digital interface (MIDI) output).

Computing device 900 may include a GPS device 909 (or corresponding interface circuitry, as discussed above). GPS device 909 may be in communication with a satellite-based system and may receive a location of computing device 900, as known in the art.

Computing device 900 may include other output device 905 (or corresponding interface circuitry, as discussed above). Examples of the other output device 905 may include an audio codec, a video codec, a printer, a wired or wireless transmitter for providing information to other devices, or an additional storage device.

Computing device 900 may include other input device 911 (or corresponding interface circuitry, as discussed above). Examples of the other input device 911 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 900 may include a security interface device 912. Security interface device 912 may include any device that provides security measures for computing device 900 such as intrusion detection, biometric validation, security encode or decode, access list management, malware detection, or spyware detection.

Computing device 900, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-9. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an integrated circuit (IC) device includes a substrate, including a first surface, an IC die, including a second surface, wherein the second surface is coupled to a first portion of the first surface, the first portion is surrounded by a second portion of the first surface, and the IC die and the substrate are electrically connected, and a frame, wherein the frame is affixed to the second portion, the frame including an alignment feature beyond an outer perimeter of the first surface, the alignment feature to mate with a complementary structure of a socket to receive the IC device.

In one or more second embodiments, further to the first embodiments, the substrate includes glass.

In one or more third embodiments, further to the first or second embodiments, the frame is a continuous metal structure coupled to the first surface and encircling an edge of the substrate.

In one or more fourth embodiments, further to the first through third embodiments, the alignment feature includes an opening to receive a keying feature of the socket.

In one or more fifth embodiments, further to the first through fourth embodiments, the frame is affixed to the second portion by an epoxy.

In one or more sixth embodiments, further to the first through fifth embodiments, the IC device also includes a heat spreader coupled to a third surface of the IC die, the third surface distal the second surface, and the heat spreader includes predominantly a material more thermally conductive than silicon.

In one or more seventh embodiments, further to the first through sixth embodiments, the heat spreader extends laterally beyond the outer perimeter of the first surface.

In one or more eighth embodiments, further to the first through seventh embodiments, the heat spreader is coupled to the frame.

In one or more ninth embodiments, further to the first through eighth embodiments, the heat spreader includes a heat pipe.

In one or more tenth embodiments, further to the first through ninth embodiments, the IC device also includes a thermal interface material between the third surface and the heat spreader.

In one or more eleventh embodiments, an integrated circuit (IC) device includes an IC die, a substrate, including an upper surface coupled to a lower surface of the IC die, a frame coupled to an outer portion of the upper surface, and a socket, wherein the socket is configured to mate to the frame.

In one or more twelfth embodiments, further to the eleventh embodiments, the frame includes an inner perimeter and an outer perimeter, the inner perimeter around the IC die, and the outer perimeter around the inner perimeter, and the socket includes a structure configured to mate with a void in the frame.

In one or more thirteenth embodiments, further to the eleventh or twelfth embodiments, the void is between the inner perimeter and the outer perimeter.

In one or more fourteenth embodiments, further to the eleventh through thirteenth embodiments, the void is in the outer perimeter and adjacent the socket.

In one or more fifteenth embodiments, an integrated circuit (IC) system includes a system substrate, a device substrate, wherein the device substrate is coupled to the system substrate by a socket, an IC die coupled to a surface of the device substrate distal the system substrate, and a frame coupled to the surface and extending beyond an outer perimeter of the device substrate, wherein the frame has an opening configured to pair with the socket.

In one or more sixteenth embodiments, further to the fifteenth embodiments, a portion of the surface surrounds the IC die and is between the IC die and the frame.

In one or more seventeenth embodiments, further to the fifteenth or sixteenth embodiments, the IC system also includes a heat spreader coupled to an upper surface of the IC die, the upper surface distal the device substrate.

In one or more eighteenth embodiments, further to the fifteenth through seventeenth embodiments, a lateral dimension of the heat spreader is greater than a lateral dimension of the device substrate.

In one or more nineteenth embodiments, further to the fifteenth through eighteenth embodiments, the IC system also includes a thermal interface material between the upper surface and the heat spreader.

In one or more twentieth embodiments, further to the fifteenth through nineteenth embodiments, the heat spreader includes a heat pipe.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) device, comprising:
a substrate, comprising a first surface, wherein the substrate comprises glass;
an IC die, comprising a second surface, wherein the second surface is coupled to a first portion of the first surface, and the first portion is surrounded by a second portion of the first surface; and
a frame, wherein the frame is affixed to the second portion, the frame comprising a feature beyond an outer perimeter of the first surface, wherein the feature comprises a notch, an opening, or a protrusion.

2. The IC device of claim 1, wherein the feature is to mate with a complementary structure of a socket to receive the IC device.

3. The IC device of claim 1, wherein the frame comprises a material other than glass.

4. The IC device of claim 3, wherein the frame is a continuous metal structure coupled to the first surface and encircling an edge of the substrate.

5. The IC device of claim 1, wherein the feature comprises an opening to receive a keying feature of the socket.

6. The IC device of claim 1, wherein the frame is affixed to the second portion by an epoxy.

7. The IC device of claim 1, further comprising a heat spreader coupled to a third surface of the IC die, the third surface distal the second surface, wherein the heat spreader comprises a metal.

8. The IC device of claim 7, wherein the heat spreader extends laterally beyond the outer perimeter of the first surface.

9. The IC device of claim 7, wherein the heat spreader is coupled to the frame.

10. The IC device of claim 7, wherein the heat spreader comprises a heat pipe.

11. The IC device of claim 7, further comprising a thermal interface material between the third surface and the heat spreader.

12. An integrated circuit (IC) device, comprising:
an IC die;
a substrate, comprising an upper surface coupled to a lower surface of the IC die, the substrate comprising glass;
a frame coupled to an outer portion of the upper surface; and
a socket, wherein the socket is configured to mate to the frame.

13. The IC device of claim 12, wherein the frame comprises an inner perimeter and an outer perimeter, the inner perimeter around the IC die, and the outer perimeter around the inner perimeter, and the socket comprises a structure configured to mate with a void in the frame.

14. The IC device of claim 13, wherein the void is between the inner perimeter and the outer perimeter.

15. The IC device of claim 13, wherein the void is in the outer perimeter and adjacent the socket.

16. An integrated circuit (IC) system, comprising:
a first substrate;
a second substrate, wherein the second substrate is coupled to the first substrate by a socket, wherein the second substrate comprises glass;
an IC die coupled to a surface of the second substrate distal the first substrate; and
a frame coupled to the surface and extending beyond an outer perimeter of the second substrate, wherein the frame has an opening configured to pair with the socket.

17. The IC system of claim 16, wherein a portion of the surface surrounds the IC die and is between the IC die and the frame.

18. The IC system of claim 16, further comprising a heat spreader, wherein the heat spreader is coupled to an upper surface of the IC die, the upper surface distal the second substrate.

19. The IC system of claim 18, wherein a lateral dimension of the heat spreader is greater than a lateral dimension of the second substrate.

20. The IC system of claim 18, wherein the heat spreader comprises a heat pipe.
